(19) United States
(12) Patent Application Publication
(10) Pub. No.: US 2014/0170317 A1
(43) Pub. Date: Jun. 19, 2014

(54) CHEMICAL VAPOR DEPOSITION OF GRAPHENE USING A SOLID CARBON SOURCE

(71) Applicant: BLUESTONE GLOBAL TECH LIMITED, Wappingers Falls, NY (US)

(72) Inventors: Xuesong Li, Wappingers Falls, NY (US); Hao Ning, Wappingers Falls, NY (US)

(73) Assignee: BLUESTONE GLOBAL TECH LIMITED, Wappingers Falls, NY (US)

(21) Appl. No.: 13/716,240

(22) Filed: Dec. 17, 2012

(51) Int. Cl. C23C 16/26

(52) U.S. Cl. CPC C23C 16/26; B82Y 40/00
USPC 427/249.6; 427/249.1; 977/843

(57) ABSTRACT

Aspects of the invention are directed to a method of forming a film on a substrate. The substrate and a solid carbon source are placed into a reactor. Subsequently, both the substrate and the solid carbon source are heated. Optionally, one or more process gases may be introduced into the reactor to help drive the formation of the film. The film comprises graphene.

### FIELD OF THE INVENTION

The present invention relates generally to the synthesis of materials, and, more particularly, to methods for the formation of graphene by chemical vapor deposition.

### BACKGROUND OF THE INVENTION

Graphene is a one-atom-thick sheet of sp²-bonded carbon arranged in a regular hexagonal pattern. Graphene is presently the target of intense study because of its many interesting and useful mechanical, optical, and electrical properties. Graphene, for example, can exhibit very high electron- and hole-mobilities and, as a result, may allow graphene-based electronic devices to display extremely high switching speeds. Graphene may also be used as an electrode material for power storage devices and displays, as a membrane material in electromechanical systems, as a membrane for the separation of gases, as a chemical sensor, and in a myriad of other applications.

Presently, high quality graphene can be formed by the repeated mechanical exfoliation of graphite. Nevertheless, graphene produced by this method tends to be limited in size. As a result, researchers have studied the chemical vapor deposition (CVD) of graphene as an alternative method of synthesis. U.S. Patent Publication No. 2011/0091647, to Colombo et al. and entitled “Graphene Synthesis by Chemical Vapor Deposition,” for example, teaches the CVD of graphene on metal and dielectric substrates using hydrogen and methane in a CVD tube reactor. Even so, there remain concerns that known CVD techniques, while being able to produce graphene films larger than those that can be formed by graphite exfoliation, may produce graphene films with qualities inferior to those found in exfoliated films. Moreover, there remain concerns about utilizing gaseous carbon sources such as methane when forming graphene by high-temperature CVD because of the risks of explosion. As a result, there is a continuing need for improved apparatus and methods for the formation of high quality graphene by CVD.

### SUMMARY OF THE INVENTION

Embodiments of the present invention address the above-identified need by providing methods for the synthesis of high quality, large area graphene by CVD.

Aspects of the invention are directed to a method of forming a film on a substrate. The substrate and a solid carbon source are placed into a reactor. Subsequently, both the substrate and the solid carbon source are heated. Optionally, one or more process gases may be introduced into the reactor to help drive the formation of the film. The film comprises graphene.

### BRIEF DESCRIPTION OF THE DRAWINGS

These and other features, aspects, and advantages of the present invention will become better understood with regard to the following description, appended claims, and accompanying drawings where:

FIGS. 1A and 1B shows an end elevational view and a side sectional view, respectively, of a CVD reactor, a substrate, and a solid carbon source configured in accordance with an illustrative embodiment of the invention;

FIG. 2 shows a schematic diagram of an illustrative gas manifold for use with the FIG. 1 CVD reactor;

FIG. 3 shows a schematic diagram of an illustrative exhaust manifold for use with the FIG. 1 CVD reactor;

FIG. 4 shows a flow diagram of a method for growing graphene using the FIG. 1 CVD reactor, substrate, and solid carbon source, in accordance with an illustrative embodiment of the invention;

FIG. 5 shows a side sectional view of a first alternative arrangement for the substrate and the solid carbon source in the FIG. 1 CVD reactor, in accordance with an illustrative embodiment of the invention;

FIG. 6 shows a side sectional view of a second alternative arrangement for the substrate and the solid carbon source in the FIG. 1 CVD reactor, in accordance with an illustrative embodiment of the invention;

FIGS. 7A and 7B show an end elevational view and a side sectional view, respectively, of a first alternative substrate and a first alternative solid carbon source for use in the FIG. 1 CVD reactor, in accordance with an illustrative embodiment of the invention;

FIGS. 8A and 8B show an end elevational view and a side sectional view, respectively, of a second alternative substrate and a second alternative solid carbon source for use in the FIG. 1 CVD reactor, in accordance with an illustrative embodiment of the invention;

FIG. 9 shows a micrograph of a graphene film formed using a method in accordance with aspects of the invention; and

FIG. 10 shows a Raman Spectrum of a graphene film formed using a method in accordance with aspects of the invention.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

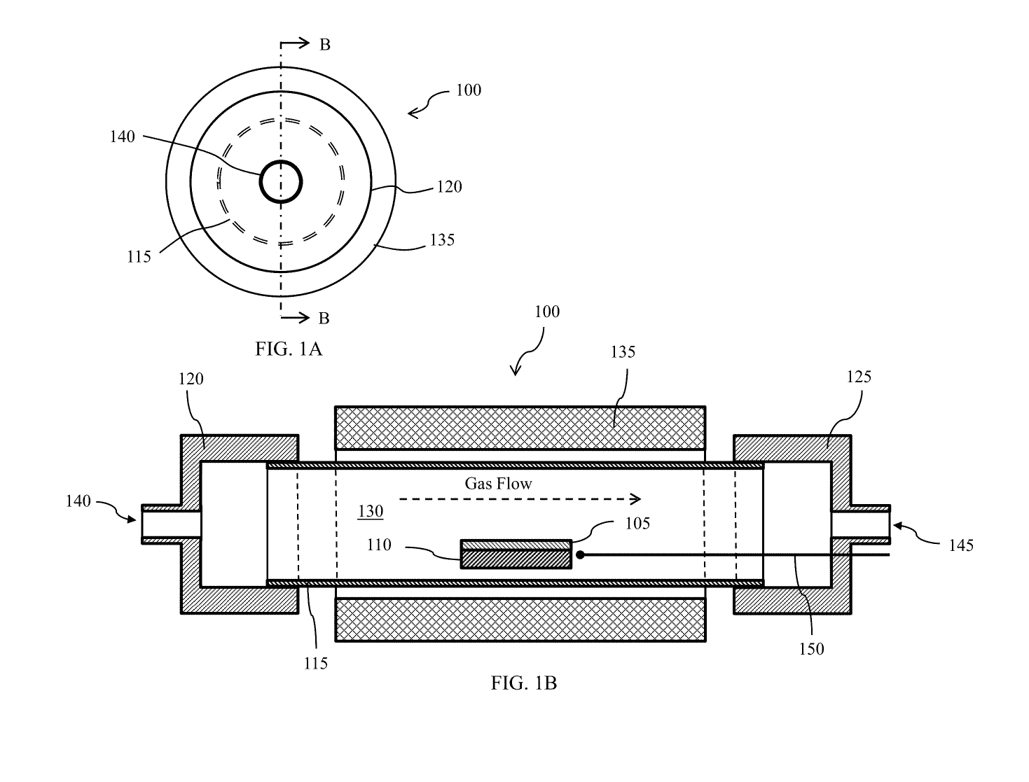

One such illustrative embodiment is shown in FIGS. 1A and 1B. More particularly, FIGS. 1A and 1B show an end elevational view and a side sectional view, respectively, of a CVD reactor 100, a substrate 105, and a solid carbon source 110 configured for graphene synthesis in accordance with an illustrative embodiment of the invention.

In the present illustrative embodiment, the CVD reactor 100 comprises several aspects of a conventional CVD tube furnace. Such CVD tube furnaces are described in many readily available publications, including, for example, A. C. Jones, Chemical Vapour Deposition: Precursors, Processes and Applications, Royal Society of Chemistry, 2009, which is hereby incorporated by reference herein. A cylindrical reaction tube 115 (e.g., quartz or alumina) is suspended between a first support end 120 and a second support end 125 so as to define a reaction space 130. This reaction space 130, in turn, is surrounded by a furnace 135 capable of heating the reaction space 130. At the first support end 120, a gas inlet port 140 allows process gases to be introduced into the reaction space 130. At the second support end 125, an exhaust gas port 145 allows process gases in the reaction space 130 to be exhausted. The substrate 105 and the solid carbon source 110 sit within the reaction space 130 near or in contact with the junction of a thermocouple 150, which allows for the measurement of temperature. In this particular case, the substrate 105 is stacked on top of the solid carbon source 110, but, as will be described below, such a configuration is only one of several alternatives falling within the scope of the invention.

The illustrative furnace 135 in the CVD reactor 100 comprises one or more resistive wire heating elements (e.g., iron-chromium-aluminum alloy) that are positioned around the reaction space 130. The coils may be supported by a hollow cylindrical high temperature insulator (e.g., ceramic fiber) that surrounds the cylindrical reaction tube 115. If desired, several distinct coils may be arranged along the longitudinal axis of the reaction space 130 to create separately-controllable heating zones. For temperature regulation, signals from the thermocouple 150 in the reaction space 130 are fed back to a power source for the furnace 135 so as to maintain a predetermined temperature set point.

FIG. 2 shows a schematic diagram of an illustrative gas manifold 200 that can be used to introduce one or more process gases into the reaction space 130 of the CVD reactor 100 via the gas inlet port 140. In the present illustrative embodiment, the gas manifold 200 comprises two process gas sources 205, 210, although this particular number of process gas sources is largely arbitrary and a gas manifold with a fewer or a greater number of process gas sources would still fall within the scope of the invention. Each process gas source 205, 210 is in gaseous communication with a respective mass flow controller 215, 220 that acts to regulate the flow rate of the process gas coming from that process gas source 205, 210 into the gas inlet port 140.

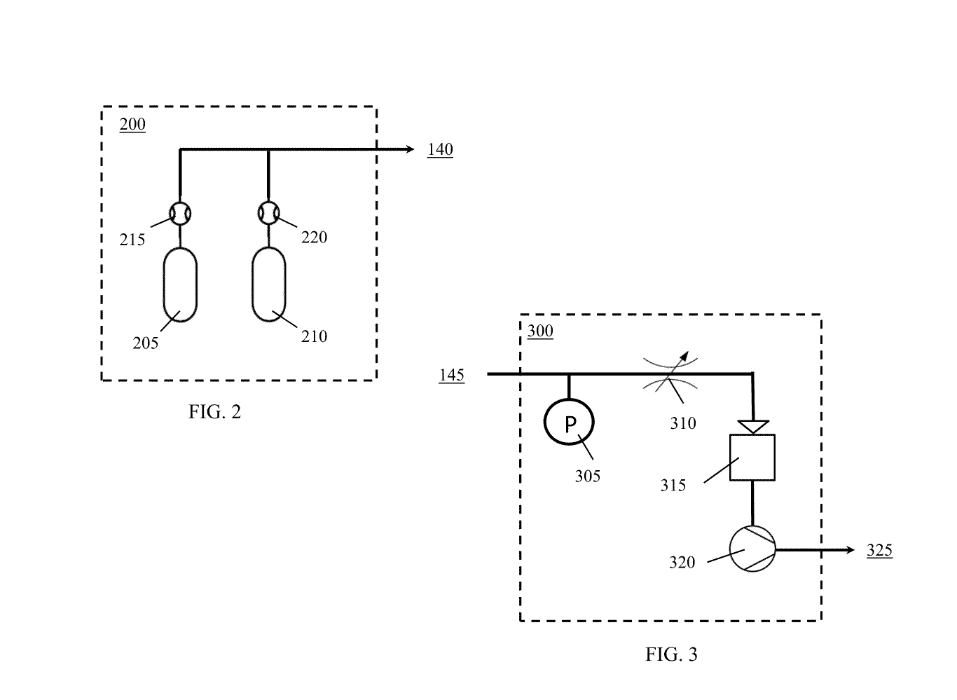

FIG. 3, moreover, shows a schematic diagram of an exhaust manifold 300 that may be used to regulate pressure in the CVD reactor 100. The exhaust manifold 300 is in gaseous communication with the reaction space 130 via the exhaust gas port 145. In the present illustrative embodiment, a gas flow, after leaving the reaction space 130 via the exhaust gas port 145, passes a pressure sensor 305 before entering a throttle valve 310. The pressure sensor 305 measures the pressure and, via a conventional electronic feedback mechanism, controls the opening of the throttle valve 310 to regulate a preset pressure in the reaction space 130. Once past the throttle valve 310, the gas flow first passes through a trap 315 (e.g., liquid nitrogen trap) and then is pumped by a rotary mechanical pump 320 before it is sent to an exhaust 325. A chemical scrubber may be provided if deemed necessary.

The solid carbon source 110 can be formed from any solid form of carbon such as graphite, diamond, amorphous carbon, or some combination thereof. The inclusion of a solid carbon source like the solid carbon source 110 is driven at least in part by the inventors' observation that such a source can, under the right process conditions, produce gaseous reactants that can deposit graphene on a substrate. Hydrogen (H₂) gas, for example, is thought to react with solid carbon under elevated temperature by the following chemical reaction:

$$\frac{m}{2} {H}_{2} ( g ) + nC ( s ) \to {C}_{n} {H}_{m} ( g ) . \qquad ( 1 )$$

The evolved hydrocarbon gas, in turn, may decompose on the hot substrate 105, which may play a role as a catalyst, by the chemical reaction:

$${C}_{n} {H}_{m} ( g ) {\to }^{substrate} nC ( graphene ) + \frac{m}{2} {H}_{2} ( g ) . \qquad ( 2 )$$

Thus, through the sequence of the chemical reactions (1) and (2), graphene is formed on the substrate by essentially transferring carbon from the solid carbon source 110 to the surface of the substrate 105. Although the solid carbon source 110 is depleted by the process, the rate of depletion is very slow and a substantial carbon source is likely to remain viable for a great multiplicity (e.g., many thousands) of deposition cycles. At the same time, the process does not require that a gaseous carbon source such as methane (CH₄) be introduced at high temperature and high partial pressure into the CVD reactor 100. The risk of explosion is thereby greatly reduced.

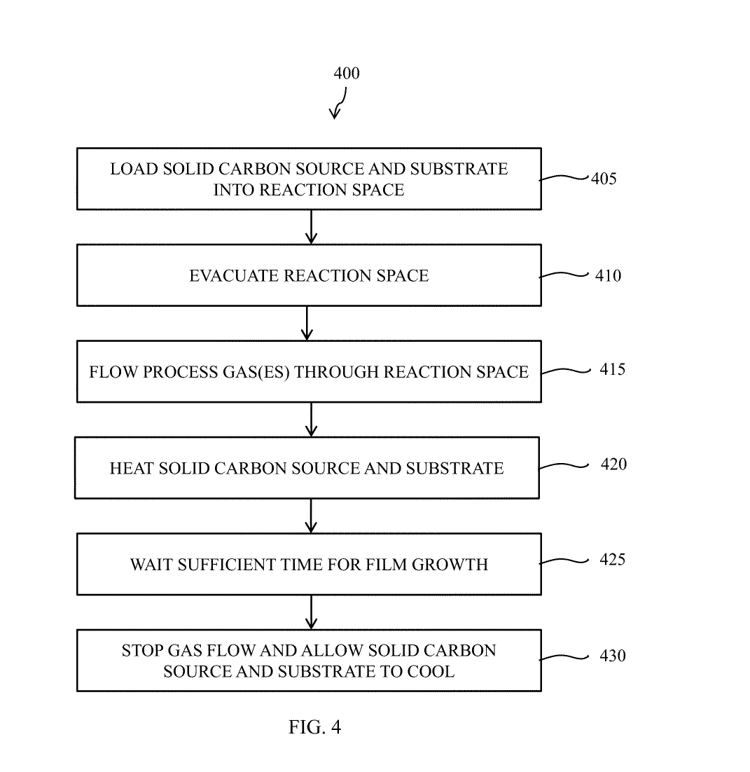

FIG. 4 shows a flow diagram of a method 400 for growing graphene using the CVD reactor 100, the substrate 105, and the solid carbon source 110, in accordance with an illustrative embodiment of the invention. In a non-limiting embodiment, the substrate 105 may comprise a metal (e.g., copper, copper and nickel, copper and cobalt, copper and ruthenium) or a dielectric (e.g., zirconium dioxide, hafnium oxide, boron nitride, aluminum oxide). Thin copper foil has been demonstrated to be a particularly good substrate for graphene synthesis by CVD and is therefore preferred, although again not limiting.

The method 400 for forming graphene is started by loading the solid carbon source 110 and the substrate 105 into the reaction space 130 of the CVD reactor 100, as indicated by step 405. The reaction space 130 is then substantially evacuated of gas by pumping the reaction space 130 down to the extent allowed by the exhaust manifold 300, as indicated in step 410. Subsequently, in step 415, a flow of one or more process gases is introduced into the reaction space 130 while maintaining a predetermined pressure utilizing the gas manifold 200 in combination with the exhaust manifold 300. The process gas flow may comprise, for example, hydrogen gas. Optionally, the hydrogen gas can be combined with an inert carrier gas such as nitrogen (N₂), helium (He), or argon (Ar). The flow rate of the hydrogen gas may be set, for example, between about one standard cubic centimeters per second (sccm) and about 100 sccm. If a carrier gas is also utilized, it may be introduced with a flow rate between about ten sccm and about 1,000 sccm. Pressure may be maintained between about 1×10⁻⁴ Torr and one atmosphere. Nevertheless, like all specified flow, pressure, temperature, and time values related herein, these particular values are merely illustrative, and alternative values are contemplated and would also come within the scope of the invention.

In step 420, the furnace 135 is utilized to heat the elements within the reaction space 130. The elements within the reaction space 130 may, for example, be heated to between about 600 degrees Celsius (° C.) and about 1,400° C. With these flow, temperature, and pressure conditions established in this manner, sufficient time is then allowed for the graphene to grow on the substrate 105, as indicated in step 425. Periods of between about 20 minutes and about 40 minutes may be sufficient. Once sufficient time has been allocated, the process gas flow is shut off and the elements within the reaction space 130 are allowed to cool to room temperature, as indicated in step 430. The substrate 105 with its graphene coating can then be removed from the CVD reactor 100.

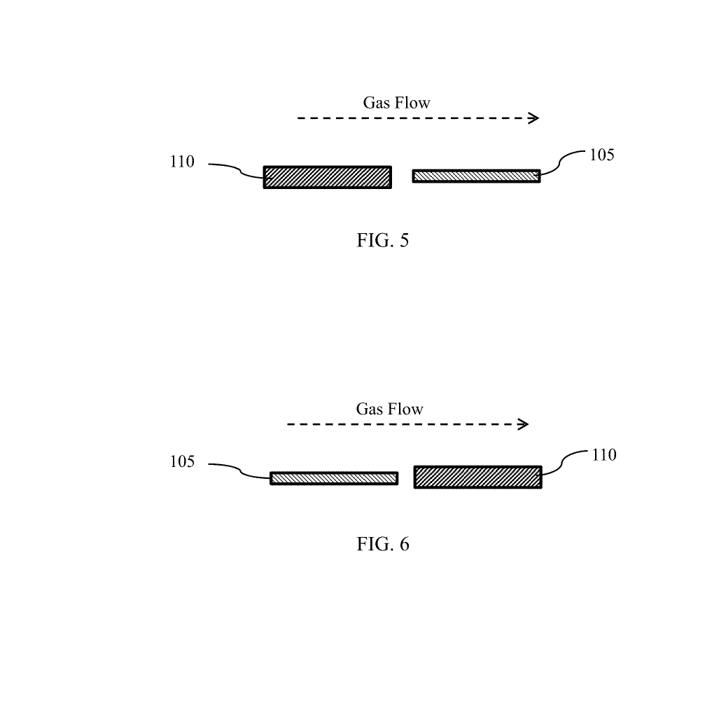

While the substrate 105 is disposed on the solid carbon source 110 in the particular embodiment shown in FIG. 1, many other arrangements of the substrate 105 and the solid carbon source 110 within the CVD reactor 100 are possible. FIG. 5 shows a side sectional view of a first alternative arrangement for the substrate 105 and the solid carbon source 110 in the CVD reactor 100. In this particular illustrative embodiment, the substrate 105, rather than being placed on top of the solid carbon source 110, is instead placed downstream of the solid carbon source 110. FIG. 6, moreover, shows a side sectional view of a second alternative arrangement for the substrate 105 and the solid carbon source 110 in the CVD reactor 100. Here, the substrate 105 is placed upstream of the solid carbon source 110.

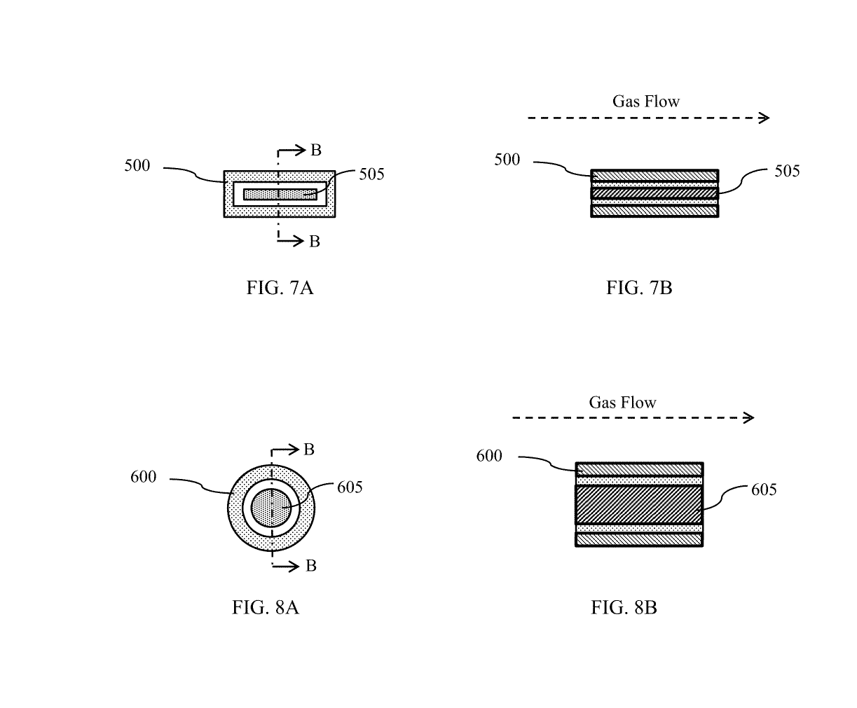

In one or more additional non-limiting alternative illustrative embodiments, a substrate (e.g., copper foil) may even be wrapped around a solid carbon source. FIGS. 7A and 7B show an end elevational view and a side sectional view, respectively, of a first alternative substrate 500 and a first alternative solid carbon source 505 for use in the CVD reactor 100. The first alternative substrate 500 forms a hollow rectangular tube that surrounds the first alternative solid carbon source 505, which describes a flat plate. FIGS. 8A and 8B show an end elevational view and a side sectional view, respectively, of a second alternative substrate 600 and a second alternative solid carbon source 605, again for use in the CVD reactor 100. In this case, the second alternative substrate 600 describes a hollow cylinder that surrounds the second alternative solid carbon source 605, which describes a cylindrical rod.

The method 400 may be used to grow a single layer of graphene on the substrate 105, or, on the other hand, to form several layers of graphene. If using hydrogen as a process gas, for example, it will be recognized from reaction (2) above that a greater availability of hydrogen gas in the reaction space 130 during graphene synthesis may help to drive the graphene growth reaction in the reverse direction, which tends to favor a fewer number of graphene layers. A lower availability of hydrogen gas in the reaction space 130, in contrast, tends to have the opposite effect and to favor a greater number of graphene layers. For this reason, modulation of the presence of hydrogen in the reaction space 130 is one effective way to control single layer graphene growth versus multi-layer graphene growth, as desired.

While the method 400 (FIG. 4) involves the intentional introduction of process gases (e.g., hydrogen and a carrier gas) into the CVD reactor 100 to form graphene on the substrate 105, it is further recognized that background gases present in the reaction space 130, even after the reaction space 130 is pumped down, may be sufficient to drive graphene growth. As a result, the growth of graphene without the intentional introduction of one or more process gases into a reaction space would also fall within the scope of the invention. For example, upon heating the CVD reactor 100, background water (H₂O) may desorb from the wall of the cylindrical reaction tube 115 and/or desorb from the walls of the gas lines in the gas manifold 200 and/or the exhaust manifold 300. The background water may, in turn, react with the hot solid carbon source 110 to produce hydrogen gas by the following reaction:

H₂O+C(s)→CO(g)+H₂(g). (3)

Subsequently, the evolved hydrogen gas may react with the hot solid carbon source 110 again via reaction (1) to form a hydrocarbon gas that ultimately acts to deposit graphene on the substrate 105 by reaction (2).

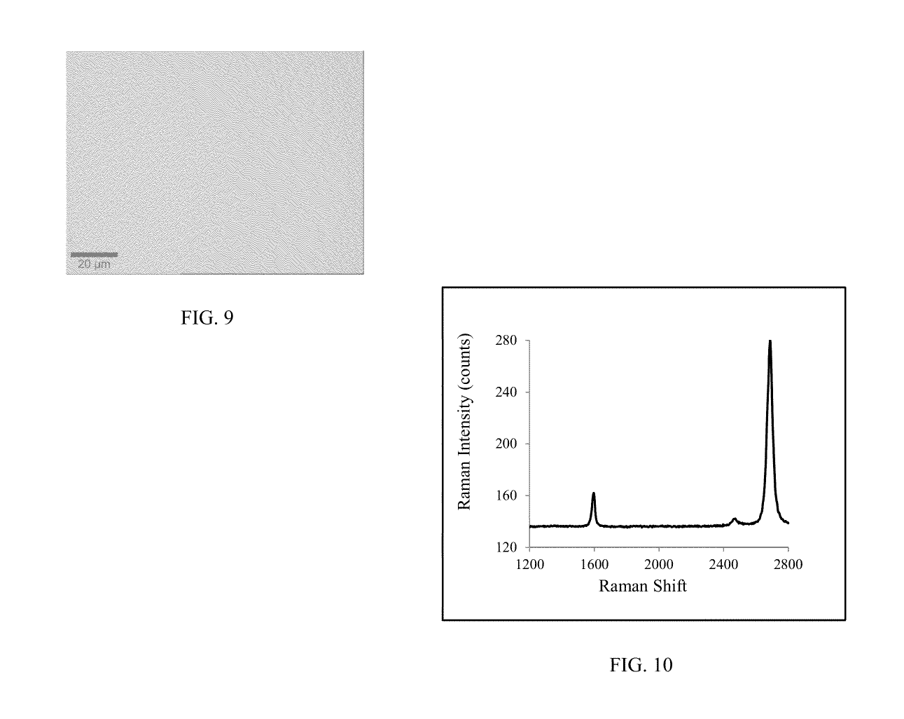

Finally, to show the efficacy of methods in accordance with aspects of the invention when actually reduced to practice, FIGS. 9 and 10 show actual laboratory results from an exemplary graphene film grown utilizing a solid carbon source in an otherwise largely conventional CVD quartz tube furnace with a two inch outer diameter and a 36 inch heating zone. The processing was initiated by loading a carbon source and a copper substrate into the reaction space with an arrangement similar to that shown in FIG. 5, and then evacuating the reaction space down to about 2×10⁻³ Torr. About two sccm of hydrogen was then introduced into the reaction space while maintaining a pressure of about 1.5×10⁻² Torr. The temperature of the reaction space was next ramped to about 1030° C. These conditions were maintained for about 20 minutes. After this time period, the hydrogen flow was ceased and the elevated temperature and reduced pressure maintained for another 20 minutes. Lastly, the substrate was allowed to cool back to room temperature and removed from the furnace.

FIG. 9 shows a micrograph of the exemplary graphene film. The graphene appears to be a very uniform single layer. FIG. 10, in turn, shows a Raman Spectrum for the same as-grown graphene film. The intensity ratio of the D-band at about 1,350 inverse-centimeters (cm⁻¹) over the G-band at about 1,600 cm⁻¹ is less than 0.03, which suggests that there are very few defects in the film. Moreover, the 2D-band at about 2,700 cm⁻¹ has a symmetric shape and has a width of about 39 cm⁻¹ while the intensity of the 2D-band is much higher than that of the G-band, which collectively indicate single layer graphene. The ability of embodiments falling within the scope of the present invention to form high quality single-layer graphene is thereby strongly reinforced by actual laboratory results.

It should again be emphasized that the above-described embodiments of the invention are intended to be illustrative only. Other embodiments can use different types and arrangements of elements for implementing the described functionality. In addition, method steps can be added, removed, rearranged, or otherwise modified. These numerous alternative embodiments within the scope of the appended claims will be apparent to one skilled in the art from the teachings herein.

All the features disclosed herein may be replaced by alternative features serving the same, equivalent, or similar purposes, unless expressly stated otherwise. Thus, unless expressly stated otherwise, each feature disclosed is one example only of a generic series of equivalent or similar features.

Any element in a claim that does not explicitly state “means for” performing a specified function or “step for” performing a specified function is not to be interpreted as a “means for” or “step for” clause as specified in 35 U.S.C. §112, ¶6. In particular, the use of “step of” in the claims herein is not intended to invoke the provisions of 35 U.S.C. §112, ¶6.

What is claimed is:

1. A method of forming a film on a substrate, the method comprising the steps of:
placing the substrate into a reactor;
placing a solid carbon source into the reactor; and
heating both the substrate and the solid carbon source in the reactor;
wherein the film comprises graphene.

2. The method of claim 1, wherein the reactor is a chemical vapor deposition reactor.

3. The method of claim 1, wherein the reactor is a chemical vapor deposition tube furnace.

4. The method of claim 1, wherein the film substantially consists of a single layer of graphene.

5. The method of claim 1, wherein the film comprises multiple layers of graphene.

6. The method of claim 1, wherein the substrate comprises a metal.

7. The method of claim 6, wherein the metal comprises copper.

8. The method of claim 1, wherein the solid carbon source comprises graphite.

9. The method of claim 1, wherein the solid carbon source comprises amorphous carbon.

10. The method of claim 1, wherein the substrate is stacked on top of the solid carbon source in the reactor.

11. The method of claim 1, wherein the substrate is placed apart from the solid carbon source in the reactor.

12. The method of claim 1, wherein the substrate at least partially surrounds the solid carbon source in the reactor.

13. The method of claim 1, further comprising the step of introducing one or more process gases into the reactor.

14. The method of claim 13, wherein the one or more process gases comprise hydrogen.

15. The method of claim 13, wherein the one or more process gases comprise nitrogen.

16. The method of claim 13, wherein the one or more process gases comprise a noble gas.

17. The method of claim 13, wherein the one or more process gases comprise hydrogen in addition to at least one of nitrogen and a noble gas.

18. The method of claim 1, wherein the heating step comprises heating the substrate and the solid carbon source to between about 600 degrees Celsius and about 1,400 degrees Celsius.

19. The method of claim 1, further comprising the step of maintaining a pressure in the reactor at less than atmospheric pressure.

20. The method of claim 1, further comprising the step of waiting a sufficient time for forming the film while the substrate and the solid carbon source are heated.
